(19) United States
(12) Patent Application Publication
(10) Pub. No.: US 2006/0176711 A1
(43) Pub. Date: Aug. 10, 2006

(54) Ornamental board for rocker panel of car

(76) Inventor: Ming-Jeng Wang, Tainan Hsien (TW)

Correspondence Address: NIKOLAI & MERSEREAU, P.A., 900 SECOND AVENUE SOUTH, SUITE 820, MINNEAPOLIS, MN, 55402, US

(21) Appl. No.: 11/054,973

(22) Filed: Feb. 10, 2005

(51) Int. Cl. F21V 7/04; H01L 33/00

(52) U.S. Cl. 362/555; 362/249

(57) ABSTRACT

An ornamental board for a rocker panel of a car includes a fixing plate having an inside formed with an elongated slot, and a photo conductive device mounted on a side of the fixing plate to emit and conduct a light outward from the elongated slot of the fixing plate. Thus, when the light emitting diodes of the light emitting unit emit light outward, the color of the background plate and the character or pattern of the photo conductive plate are projected outward from the elongated slot of the fixing plate, thereby enhancing the aesthetic quality of the rocker panel of the car by provision of the ornamental board.

### BACKGROUND OF THE INVENTION

1. Field of the Invention

The present invention relates to an ornamental board, and more particularly to an ornamental board for a rocker panel of a car.

2. Description of the Related Art

A conventional light emitting body is mounted on a car to indicate a pattern or character so as to enhance the aesthetic quality of the car. The conventional light emitting body comprises a light permeable plate provided with a pattern or character, and a luminescent plate to indicate the pattern or character of the light permeable plate. However, the luminescent plate needs an alternating current voltage of 110 volts that cannot be supplied by the direct current voltage of 12 volts of the car, so that it is necessary to provide a transformer additionally so as to transform the direct current voltage of 12 volts of the car into the alternating current voltage of 110 volts, thereby causing inconvenience to the user, and thereby easily causing danger to the user when an electricity leakage happens.

### SUMMARY OF THE INVENTION

In accordance with the present invention, there is provided an ornamental board, comprising a fixing plate having an inside formed with an elongated slot; and a photo conductive device mounted on a side of the fixing plate to emit and conduct a light outward from the elongated slot of the fixing plate.

The primary objective of the present invention is to provide an ornamental board having an outstanding outer appearance.

Another objective of the present invention is to provide an ornamental board, wherein when the light emitting diodes of the light emitting unit emit light outward, the color of the background plate and the character or pattern of the photo conductive plate are projected outward from the elongated slot of the fixing plate, thereby enhancing the aesthetic quality of the rocker panel of the car by provision of the ornamental board.

A further objective of the present invention is to provide an ornamental board, wherein the ornamental board is mounted on the rocker panel of the car easily and conveniently, thereby facilitating a user mounting the ornamental board.

A further objective of the present invention is to provide an ornamental board, wherein the fixing plate of the ornamental board is directly mounted on the rocker panel of the car without having to form a receiving space to receive the ornamental board, thereby preventing the ornamental board from breaking the structural strength of the car.

Further benefits and advantages of the present invention will become apparent after a careful reading of the detailed description with appropriate reference to the accompanying drawings.

### BRIEF DESCRIPTION OF THE DRAWINGS

FIG. 1 is an exploded perspective view of an ornamental board in accordance with the preferred embodiment of the present invention;

FIG. 2 is a partially cut-away top plan assembly view of the ornamental board as shown in FIG. 1;

FIG. 3 is a plan cross-sectional view of the ornamental board taken along line 3-3 as shown in FIG. 2; and

FIG. 4 is a perspective view showing the ornamental board being mounted on a rocker panel of a car.

### DETAILED DESCRIPTION OF THE INVENTION

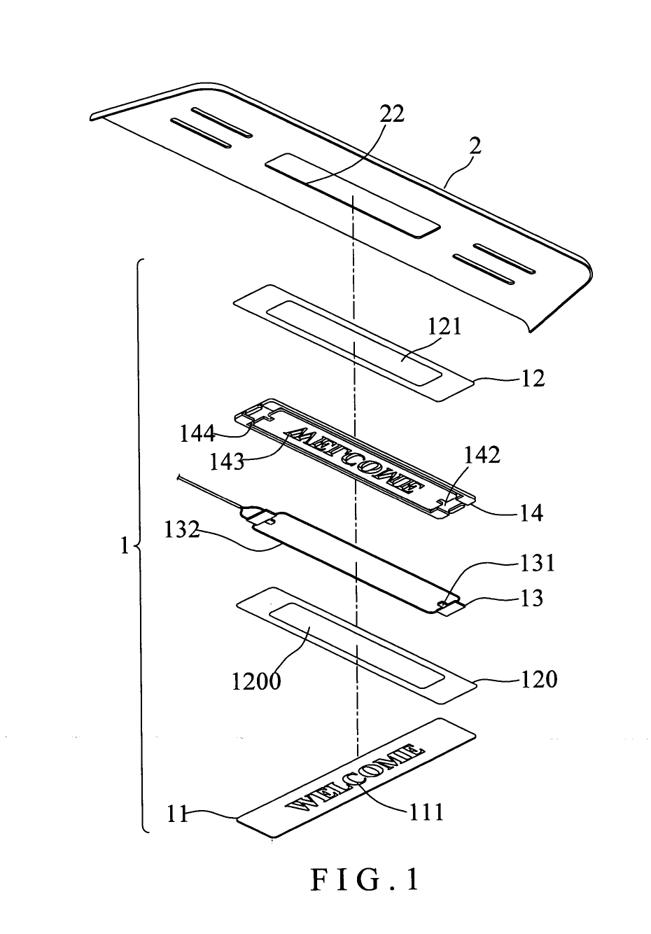

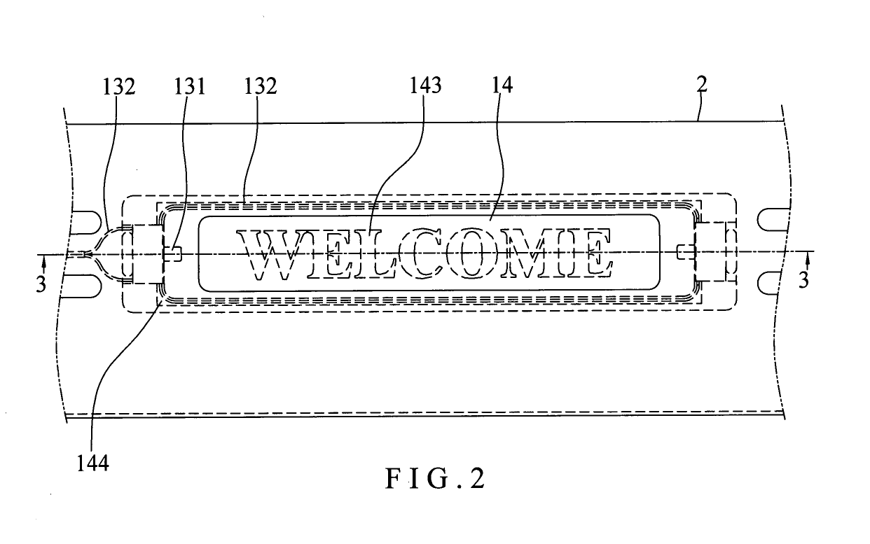

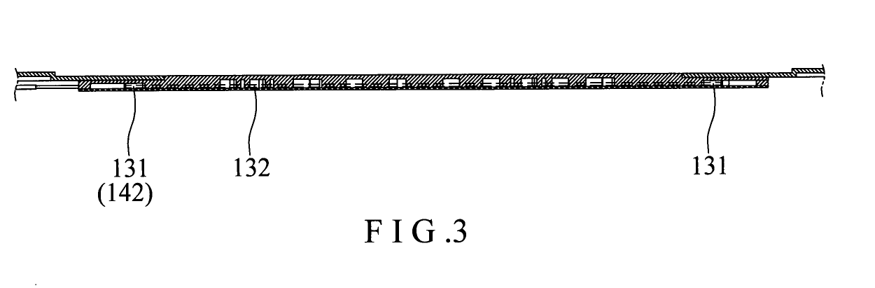

Referring to the drawings and initially to FIGS. 1-3, an ornamental board for a rocker panel of a car in accordance with the preferred embodiment of the present invention comprises a fixing plate 2 having an inside formed with an elongated slot 22, and a photo conductive device 1 mounted on a side of the fixing plate 2 to emit and conduct a light outward from the elongated slot 22 of the fixing plate 2.

The photo conductive device 1 is mounted in the elongated slot 22 of the fixing plate 2 and includes a photo conductive plate 14 having a first side mounted on the side of the fixing plate 2, a light emitting unit 13 having a first side mounted on a second side of the photo conductive plate 14, and a background plate 11 having a side mounted on a second side of the light emitting unit 13.

The background plate 11 is a colored reflective plate that can reflect a color onto the photo conductive plate 14.

The light emitting unit 13 is provided with two opposite light emitting diodes (LEDs) 131 and an electric wire 132 connected to the light emitting diodes 131. The light emitting diodes 131 of the light emitting unit 13 are connected in parallel. Thus, when the electric wire 132 of the light emitting unit 13 is connected to the direct current voltage of 12 volts supplied by the car, the light emitting diodes 131 of the light emitting unit 13 emit light outward to project the color of the background plate 11 onto the photo conductive plate 14.

The photo conductive plate 14 is a transparent plate having two ends each formed with a receiving recess 142 to receive a respective one of the light emitting diodes 131 of the light emitting unit 13. The photo conductive plate 14 has a mediate portion provided with a character or pattern 143 exposed outward from the elongated slot 22 of the fixing plate 2. Preferably, the background plate 11 has a mediate portion provided with a character or pattern 111 matching the character or pattern 143 of the photo conductive plate 14. The photo conductive plate 14 has a periphery formed with a guide groove 144 to receive the electric wire 132 of the light emitting unit 13, so that the electric wire 132 of the light emitting unit 13 is hidden in the photo conductive plate 14.

The photo conductive device 1 further includes a first adhesive plate 12 mounted between the first side of the photo conductive plate 14 and the side of the fixing plate 2 to bond the photo conductive plate 14 onto the fixing plate 2, and a second adhesive plate 120 mounted between the side of the background plate 11 and the second side of the light emitting unit 13 to bond the background plate 11 onto the light emitting unit 13. The first adhesive plate 12 is a double adhesive plate having an inside formed with an elongated slot 121 aligning with the elongated slot 22 of the fixing plate 2. The first adhesive plate 12 is bonded around a periphery of the elongated slot 22 of the fixing plate 2. The second adhesive plate 120 is a double adhesive plate having an inside formed with an elongated slot 1200 aligning with the elongated slot 22 of the fixing plate 2.

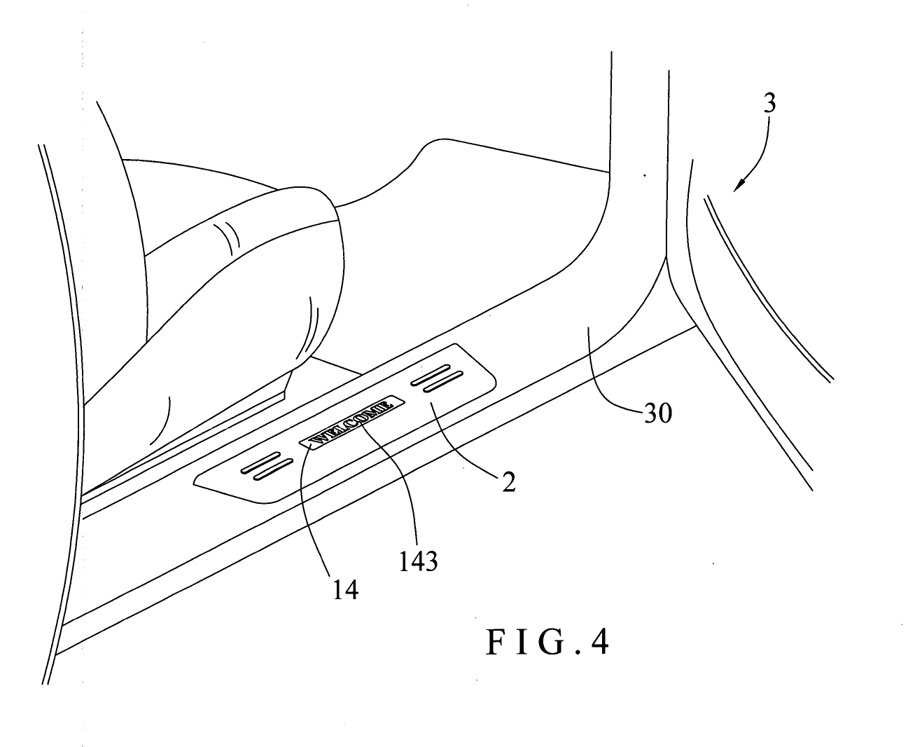

In assembly, as shown in FIGS. 1-4, the fixing plate 2 of the ornamental board is secured on a rocker panel 30 of a car 3, and the electric wire 132 of the light emitting unit 13 is connected to the direct current voltage of 12 volts supplied by the car 3. Thus, when the light emitting diodes 131 of the light emitting unit 13 emit light outward, the color of the background plate 11 and the character or pattern 143 of the photo conductive plate 14 are projected outward from the elongated slot 22 of the fixing plate 2, thereby enhancing the aesthetic quality of the rocker panel 30 of the car 3 by provision of the ornamental board.

Accordingly, when the light emitting diodes 131 of the light emitting unit 13 emit light outward, the color of the background plate 11 and the character or pattern 143 of the photo conductive plate 14 are projected outward from the elongated slot 22 of the fixing plate 2, thereby enhancing the aesthetic quality of the rocker panel 30 of the car 3 by provision of the ornamental board. In addition, the ornamental board is mounted on the rocker panel 30 of the car 3 easily and conveniently, thereby facilitating a user mounting the ornamental board. Further, the fixing plate 2 of the ornamental board is directly mounted on the rocker panel 30 of the car 3 without having to form a receiving space to receive the ornamental board, thereby preventing the ornamental board from breaking the structural strength of the car.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

What is claimed is:

1. An ornamental board, comprising:
a fixing plate having an inside formed with an elongated slot; and
a photo conductive device mounted on a side of the fixing plate to emit and conduct a light outward from the elongated slot of the fixing plate.

2. The ornamental board in accordance with claim 1, wherein the photo conductive device is mounted in the elongated slot of the fixing plate.

3. The ornamental board in accordance with claim 1, wherein the photo conductive device includes a photo conductive plate having a first side mounted on the side of the fixing plate, a light emitting unit having a first side mounted on a second side of the photo conductive plate, and a background plate having a side mounted on a second side of the light emitting unit.

4. The ornamental board in accordance with claim 3, wherein the background plate is a colored reflective plate.

5. The ornamental board in accordance with claim 3, wherein the background plate reflects a color onto the photo conductive plate.

6. The ornamental board in accordance with claim 3, wherein the light emitting unit is provided with two opposite light emitting diodes and an electric wire connected to the light emitting diodes.

7. The ornamental board in accordance with claim 6, wherein the light emitting diodes of the light emitting unit are connected in parallel.

8. The ornamental board in accordance with claim 6, wherein when the electric wire of the light emitting unit is connected to a direct current voltage of volts supplied by a car, the light emitting diodes of the light emitting unit emit light outward to project a color of the background plate onto the photo conductive plate.

9. The ornamental board in accordance with claim 3, wherein the photo conductive plate is a transparent plate.

10. The ornamental board in accordance with claim 6, wherein the photo conductive plate has two ends each formed with a receiving recess to receive a respective one of the light emitting diodes of the light emitting unit.

11. The ornamental board in accordance with claim 3, wherein the photo conductive plate has a mediate portion provided with a character or pattern exposed outward from the elongated slot of the fixing plate.

12. The ornamental board in accordance with claim 11, wherein the background plate has a mediate portion provided with a character or pattern matching the character or pattern of the photo conductive plate.

13. The ornamental board in accordance with claim 6, wherein the photo conductive plate has a periphery formed with a guide groove to receive the electric wire of the light emitting unit, so that the electric wire of the light emitting unit is hidden in the photo conductive plate.

14. The ornamental board in accordance with claim 3, wherein the photo conductive device further includes a first adhesive plate mounted between the first side of the photo conductive plate and the side of the fixing plate to bond the photo conductive plate onto the fixing plate, and a second adhesive plate mounted between the side of the background plate and the second side of the light emitting unit to bond the background plate onto the light emitting unit.

15. The ornamental board in accordance with claim 14, wherein the first adhesive plate is a double adhesive plate having an inside formed with an elongated slot aligning with the elongated slot of the fixing plate.

16. The ornamental board in accordance with claim 14, wherein the first adhesive plate is bonded around a periphery of the elongated slot of the fixing plate.

17. The ornamental board in accordance with claim 14, wherein the second adhesive plate is a double adhesive plate having an inside formed with an elongated slot aligning with the elongated slot of the fixing plate.
